(19) United States
(12) Patent Application Publication
(10) Pub. No.: US 2023/0253937 A1
(43) Pub. Date: Aug. 10, 2023

(54) POWER AMPLIFIER CIRCUIT AND COMMUNICATION DEVICE

(71) Applicant: Murata Manufacturing Co., Ltd., Kyoto (JP)

(72) Inventors: Satoshi TANAKA, Kyoto (JP); Seima KONDO, Kyoto (JP); Yasuhisa YAMAMOTO, Kyoto (JP)

(21) Appl. No.: 18/299,778

(22) Filed: Apr. 13, 2023

Related U.S. Application Data
(63) Continuation of application No. PCT/JP2021/037820, filed on Oct. 13, 2021.

(30) Foreign Application Priority Data
Oct. 14, 2020 (JP) 2020-173458

(51) Int. Cl. H03F 3/24; H04B 1/40

(52) U.S. Cl. CPC H03F 3/245; H04B 1/40; H03F 2200/171; H03F 2200/451

(57) ABSTRACT

Provided are a power amplifier circuit and a communication device that improve a power handling capability required for a filter while increasing output power. A power amplifier circuit includes: an amplifier unit that amplifies an input signal of a time division duplex scheme and outputs a signal to a signal path and a signal to a signal path; a filter that is provided in the signal path and outputs a signal based on the signal; a filter that is provided in the signal path and outputs a signal based on the signal; and a transformer that is connected to the signal path through the filter and connected to the signal path through the filter and outputs an output signal based on the signal and the signal to a signal path.

### CROSS REFERENCE TO RELATED APPLICATION

This is a continuation of International Application No. PCT/JP2021/037820 filed on Oct. 13, 2021 which claims priority from Japanese Patent Application No. 2020-173458 filed on Oct. 14, 2020. The contents of these applications are incorporated herein by reference in their entireties.

### BACKGROUND ART

### Technical Field

The present disclosure relates to a power amplifier circuit and a communication device.

A power amplifier circuit that amplifies a radio frequency (RF) signal is used for communication in a mobile object such as a mobile terminal. The power amplifier circuit is required to perform power amplification corresponding to a plurality of communication schemes and a plurality of frequency bands.

Patent Document 1 discloses a communication unit corresponding to a plurality of communication schemes and a plurality of frequency bands. In the communication unit disclosed in Patent Document 1, a duplexer is connected to each of outputs of a plurality of power amplifiers corresponding to the respective frequency bands, and each duplexer is connected to an antenna through a switch and a diplexer.
Patent Document 1: U.S. Pat. No. 9,642,103

### BRIEF SUMMARY

With the development of communication standards, the number of frequency bands using a time division duplex (TDD) scheme as a communication scheme has increased with respect to the number of frequency bands using a frequency division duplex (FDD) scheme. In addition, the number of frequency bands used for communication has increased.

Due to an increase in frequency bands using the TDD scheme, an increase in frequency bands supported by a power amplifier circuit, and the like, an increase in the output of the power amplifier circuit has been demanded. In the circuit of Patent Document 1, when the output from the power amplifier increases, the power applied to the duplexer, which is a filter, increases. If the power applied to the filter exceeds the withstand power of the filter, for example, the filter is damaged, and the functions of the filter and the power amplifier circuit are impaired.

The present disclosure provides a power amplifier circuit and a communication device that improve the power handling capability required for the filter while increasing the output power.

A power amplifier circuit according to an aspect of the present disclosure includes: an amplifier unit that amplifies an input signal of a time division duplex scheme and outputs a first signal to a first signal path and a second signal to a second signal path; a first filter that is provided in the first signal path and outputs a third signal based on the first signal; a second filter that is provided in the second signal path and outputs a fourth signal based on the second signal; and a signal output unit that is connected to the first signal path through the first filter and connected to the second signal path through the second filter and outputs an output signal based on the third signal and the fourth signal to a third signal path.

According to the present disclosure, it is possible to provide a power amplifier circuit that improves the power handling capability required for the filters while increasing the output power.

### BRIEF DESCRIPTION OF THE DRAWINGS

FIG. 1 is a circuit diagram of a communication module including a power amplifier circuit according to a first embodiment.

FIG. 2 is a circuit diagram of a power amplifier circuit according to a second embodiment.

FIG. 3 is a circuit diagram of another power amplifier circuit according to the second embodiment.

FIG. 4 is a circuit diagram of a power amplifier circuit according to a third embodiment.

FIG. 5 is a circuit diagram of a power amplifier circuit according to a fourth embodiment.

FIG. 6 is a circuit diagram of a power amplifier circuit according to a fifth embodiment.

FIG. 7 is another circuit diagram of the power amplifier circuit according to the fifth embodiment.

FIG. 8 is another circuit diagram of the power amplifier circuit according to the fifth embodiment.

FIG. 9 is a circuit diagram of a power amplifier circuit according to a sixth embodiment.

FIG. 10 is a circuit diagram of a power amplifier circuit according to a seventh embodiment.

FIG. 11 is a circuit diagram of a power amplifier circuit according to an eighth embodiment.

FIG. 12 is another circuit diagram of the power amplifier circuit according to the eighth embodiment.

FIG. 13 is a circuit diagram of a power amplifier circuit according to a ninth embodiment.

FIG. 14 is a circuit diagram of a power amplifier circuit according to a tenth embodiment.

FIG. 15 is another circuit diagram of the power amplifier circuit according to the tenth embodiment.

### DETAILED DESCRIPTION

Hereinafter, embodiments of the present disclosure will be described in detail with reference to the drawings. Note that the same elements are denoted by the same reference numerals, and redundant description thereof will be omitted as much as possible.

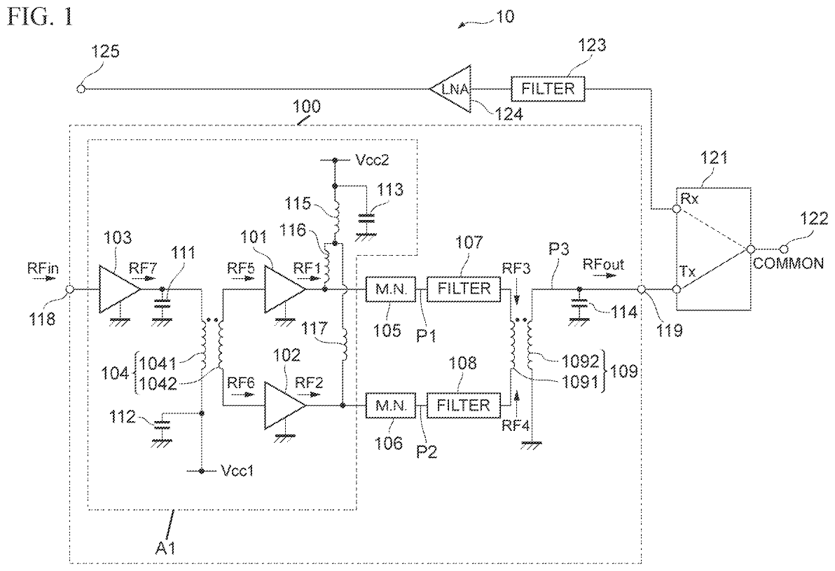

A first embodiment will be described. FIG. 1 illustrates a circuit diagram of a power amplifier circuit 100 according to the first embodiment and a communication module 10 including the power amplifier circuit 100. The communication module 10 includes the power amplifier circuit 100, a switch 121, an antenna terminal 122, a filter 123, and a low noise amplifier 124.

The power amplifier circuit 100 includes amplifiers 101, 102, and 103, transformers 104 and 109, matching circuits 105 and 106, filters 107 and 108, capacitors 111, 112, 113, and 114, and inductors 115, 116, and 117. The power amplifier circuit 100 further includes signal paths P1, P2, and P3.

The amplifier 101 (first amplifier) is provided in the signal path P1. The input of the amplifier 101 is connected to the transformer 104. A power supply voltage Vcc2 (second power supply voltage) is supplied to the amplifier 101 through the inductor 115 and the inductor 116. The amplifier 101 amplifies a signal RF5 and outputs a signal RF1 to the signal path P1.

The amplifier 102 (second amplifier) is provided in the signal path P2. The input of the amplifier 102 is connected to the transformer 104. The power supply voltage Vcc2 is supplied to the amplifier 102 through the inductor 115 and the inductor 117. The amplifier 102 amplifies a signal RF6 and outputs a signal RF2 to the signal path P2. Note that the power supply voltage Vcc2 may be the same power supply voltage as a power supply voltage Vcc1.

In the amplifier 103 (third amplifier), a module input terminal 118 is connected to the input of the amplifier 103, and the transformer 104 is connected to the output of the amplifier 103. The power supply voltage Vcc1 (first power supply voltage) is supplied to the amplifier 103 through the transformer 104. The amplifier 101 amplifies an input signal Raffin input through the module input terminal 118 and outputs a signal RF7. The signal RF7 is divided into the signal RF5 and the signal RF6 by the transformer 104.

The signal RF5 is output to the signal path P1, and the signal RF6 is output to the signal path P2.

The signal path P1 (first signal path) is a path through which a signal to be amplified and a signal amplified by the amplifier 101 flow. The signal path P1 is constituted by the amplifier 101, the matching circuit 105, the filter 107, and a wiring. The signal path P2 (second signal path) is a path through which a signal to be amplified and a signal amplified by the amplifier 102 flow. The signal path P2 is constituted by the amplifier 102, the matching circuit 106, the filter 108, and a wiring.

The amplifiers 101, 102, and 103 include, for example, a transistor such as a heterojunction bipolar transistor (HBT). Although the embodiments of the present disclosure are heterojunction bipolar transistors, field effect transistors (FETs) may also be used.

The transformer 104 (first transformer) includes a primary winding 1041 and a secondary winding 1042. The primary winding 1041 has one end connected to the output of the amplifier 103, and the other end supplied with the power supply voltage Vcc1 of the amplifier 103. The secondary winding 1042 has one end connected to the input of the amplifier 101, and the other end connected to the input of the amplifier 102. The secondary winding 1042 is electromagnetically coupled to the primary winding 1041.

The transformer 104 performs unbalanced-balanced conversion based on the signal RF7, which is an unbalanced signal from the amplifier 103, outputs the signal RF5 from one end of the secondary winding 1042, and outputs the signal RF6 from the other end of the secondary winding 1042. A difference in phase between the signal RF5 and the signal FRO is about 180°, and the signal RF5 and the signal RF6 are signals having phases opposite to each other. The transformer 104 functions as a signal dividing unit. The transformer 104 also has a function of performing impedance matching between the output impedance of the amplifier 103 and the input impedance of the amplifiers 101 and 102.

The matching circuit 105 is provided between the amplifier 103 and the filter 107 in the signal path P1. The matching circuit 105 is a circuit that adjusts the impedance between the output of the amplifier 103 and the input of the filter 107. The matching circuit 106 is provided between the amplifier 102 and the filter 108 in the signal path P2. The matching circuit 106 is a circuit that adjusts the impedance between the output of the amplifier 102 and the input of the filter 108.

The filter 107 (first filter) is provided between the matching circuit 105 and the transformer 109 in the signal path P1. The filter 107 outputs, to the transformer 109, a signal RF3 obtained by filtering the signal RF1 input from the amplifier 101 through the matching circuit 105 to a predetermined frequency band (band).

The filter 108 (second filter) is provided between the matching circuit 106 and the transformer 109 in the signal path P2. The filter 108 outputs, to the transformer 109, a signal RF4 obtained by filtering the signal RF2 input from the amplifier 102 through the matching circuit 106 to the same frequency band as the filter 107.

The filters 107 and 108 are, for example, acoustic wave filters, and surface acoustic wave (SAW) filters, bulk acoustic wave (BAW) filters, or ceramic filters can be used. The filters 107 and 108 function as band-pass filters.

The transformer 109 (second transformer) includes a primary winding 1091 and a secondary winding 1092. The primary winding 1091 has one end connected to the output of the filter 107, and the other end connected to the output of the filter 108. The secondary winding 1092 has one end connected to an output end 119 through the signal path P3, and the other end connected to the ground. The secondary winding 1092 is electromagnetically coupled to the primary winding 1091.

The transformer 109 outputs an output signal RFout, which is an unbalanced signal, to the signal path P3 (third signal path) based on the signal RF3 and the signal RF4, which are balanced signals. The transformer 109 functions as a signal output unit.

The capacitor 111 has one end connected between the output of the amplifier 103 and one end of the primary winding 1041, and the other end connected to the ground. The capacitor 111 is provided to adjust the impedance of the primary winding 1041 as seen from the output of the amplifier 103.

The capacitor 112 has one end connected to the other end of the primary winding 1041, and the other end connected to the ground. The capacitor 112 is provided for stabilization of the power supply voltage Vcc1 supplied to the amplifier 103.

The capacitor 113 has one end connected between the inductor 115 and the power supply voltage Vcc2, and the other end connected to the ground. The capacitor 113 is provided for noise removal and stabilization of the power supply voltage Vcc2 supplied to the amplifiers 101 and 102.

The capacitor 114 has one end connected between one end of the secondary winding 1092 and the output end 119, and the other end connected to the ground. The capacitor 114 is provided to adjust the impedance of the output end 119 as seen from the one end of the secondary winding 1092.

The inductor 115 is an inductance element corresponding to the inductance of a wiring. The inductor 116 has one end connected to the inductor 115 and the other end connected to the amplifier 101. The inductor 117 has one end connected to the inductor 115 and the other end connected to the amplifier 102. The inductors 115 and 116 function as choke inductors when the power supply voltage Vcc2 is supplied to the amplifier 101. The inductors 115 and 117 function as choke inductors when the power supply voltage Vcc2 is supplied to the amplifier 102.

The power amplifier circuit 100 amplifies the input signal RFin of the time division duplex (TDD) scheme and outputs the output signal RFout. In the power amplifier circuit 100, an amplifier unit A1 including the amplifiers 101, 102, and 103, the transformer 104, the capacitors 111, 112, and 113, and the inductors 115, 116, and 117 outputs the signal RF1 and the signal RF2 to the signal paths P1 and P2, respectively, based on the input signal RFin.

Specifically, the power amplifier circuit 100 divides the signal RF7 based on the input signal RFin into the signal RF5 and the signal RF6 by using the transformer 104. The signal RF1 obtained by amplifying the signal RF5 by the amplifier 101 is input to the filter 107 through the matching circuit 105.

The signal RF2 obtained by amplifying the signal RF6 by the amplifier 102 is input to the filter 108 through the matching circuit 106. The signal RF3 based on the signal RF1 is output from the filter 107. The signal RF4 based on the signal RF2 is output from the filter 108. The signal RF3 and the signal RF4 are combined by the transformer 109, and the output signal RFout is output through the signal path P3.

The output signal RFout amplified by the power amplifier circuit 100 is output to the switch 121 through the output end 119.

The switch 121 is a switch including a transmission terminal Tx, a reception terminal Rx, and a common terminal COMMON. Based on an external control signal, the switch 121 connects the transmission terminal Tx and the common terminal COMMON at the time of signal transmission, and connects the reception terminal Rx and the common terminal COMMON at the time of signal reception. If a signal of the TDD scheme is used, the switch 121 switches the connection between the common terminal COMMON and the transmission terminal Tx or the reception terminal Rx in accordance with time.

The antenna terminal 122 is a terminal connected to the common terminal COMMON. The communication module 10 transmits and receives signals through an antenna connected to the antenna terminal 122.

The filter 123 is connected to the reception terminal Rx. The filter 123 filters the reception signal input through the antenna terminal 122 and the switch 121 to a predetermined frequency band and outputs the filtered signal to the low noise amplifier 124.

The low noise amplifier (LNA) 124 amplifies the reception signal input from the filter 123. The amplified reception signal is output through a terminal 125 and subjected to suitable signal processing.

In the power amplifier circuit 100, the power of the signal filtered by the filters 107 and 108 is about half of the power of the output signal RFout. Therefore, the power handling capability of the filters 107 and 108 only needs to withstand half the power in a case where the output signal RFout is filtered. That is, in the power amplifier circuit 100, it is possible to improve the power handling capability required for the filters while increasing the power of the output signal RFout. Since the conditions required for the power handling capability are relaxed, SAW filters or BAW filters that can easily implement steep filter characteristics can be used as the filters.

A second embodiment will be described. In the second and subsequent embodiments, descriptions of matters common to those in the first embodiment will be omitted, and only different points will be described. In particular, substantially the same functions and effects obtained by substantially the same configurations will not be sequentially described for each embodiment.

Although the communication module 10 including the power amplifier circuit 100 has been described in the first embodiment, only a power amplifier circuit that outputs the output signal RFout to the switch 121 will be described in the second and subsequent embodiments. As in the power amplifier circuit 100 according to the first embodiment, it is possible to configure a communication module including the power amplifier circuit described in the second and subsequent embodiments.

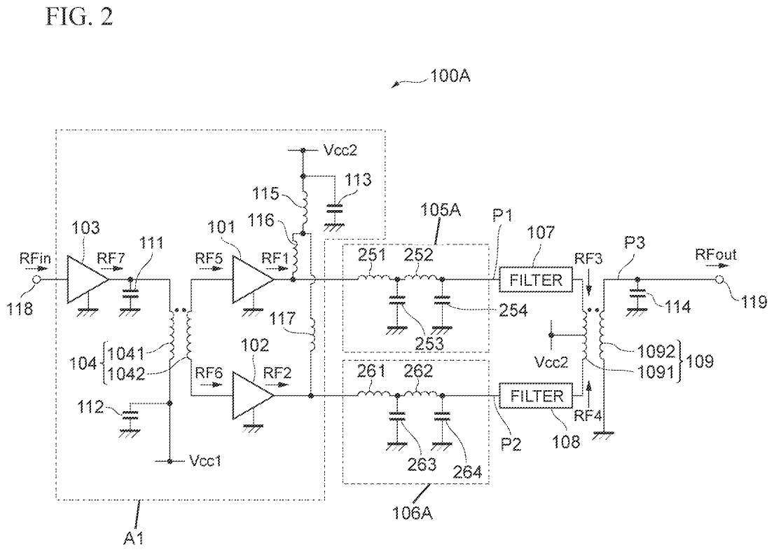

FIG. 2 illustrates a circuit diagram of a power amplifier circuit 100A according to the second embodiment. In the power amplifier circuit 100A, the configurations of the matching circuit 105 and the matching circuit 106 are specifically illustrated as a matching circuit 105A (first matching circuit) and a matching circuit 106A (second matching circuit).

The matching circuit 105A includes inductors 251 and 252 and capacitors 253 and 254. The inductors 251 and 252 are provided in series to the signal path P1 between the output of the amplifier 101 and the input of the filter 107. The capacitor 253 has one end connected between the inductor 251 and the inductor 252, and the other end connected to the ground. The capacitor 254 has one end connected between the inductor 252 and the input of the filter 107, and the other end connected to the ground.

In the matching circuit 105A, the input of the filter 107 is supplied with the power supply voltage Vcc2 through the inductors 115, 116, 251, and 252.

The matching circuit 106A includes inductors 261 and 262 and capacitors 263 and 264. The matching circuit 106A is provided in the signal path P2 in the same manner as the matching circuit 105A is provided in the signal path P1. The power supply voltage Vcc2 is supplied to the input of the filter 108.

In the power amplifier circuit 100A, the power supply voltage Vcc2 is supplied to the primary winding 1091. The power supply voltage Vcc2 is supplied to the primary winding 1091 through, for example, a midpoint of the primary winding 1091. The power supply voltage Vcc2 is supplied to the output of the filter 107 and the output of the filter 108 through the primary winding 1091. Note that the midpoint in the present disclosure includes a variation of about ±15% of the inductance value, which is a half value of the primary winding 1091.

In the power amplifier circuit 100A, the matching circuits 105A and 106A are configured such that the power supply voltage Vcc2 is applied to the input of each of the filters 107 and 108. In this case, by supplying the power supply voltage Vcc2 to the outputs of the filters 107 and 108 through the primary winding 1091, it is possible to prevent a difference in direct-current voltage from occurring between the inputs and the outputs of the filters 107 and 108.

If a difference in direct-current voltage occurs between the inputs and the outputs of the filters 107 and 108, a voltage difference exceeding the withstand voltage of the filters may occur between the inputs and the outputs of the filters 107 and 108 depending on the voltage amplitude of the signal. In this case, it is difficult to increase the power input to the filters 107 and 108. That is, the power handling capability of the filters 107 and 108 deteriorates. By supplying the same direct-current voltage to the inputs and the outputs of the filters 107 and 108 in the power amplifier circuit 100A, it is possible to suppress the occurrence of a difference in direct-current voltage between the inputs and the outputs of the filters 107 and 108 and improve the power handling capability.

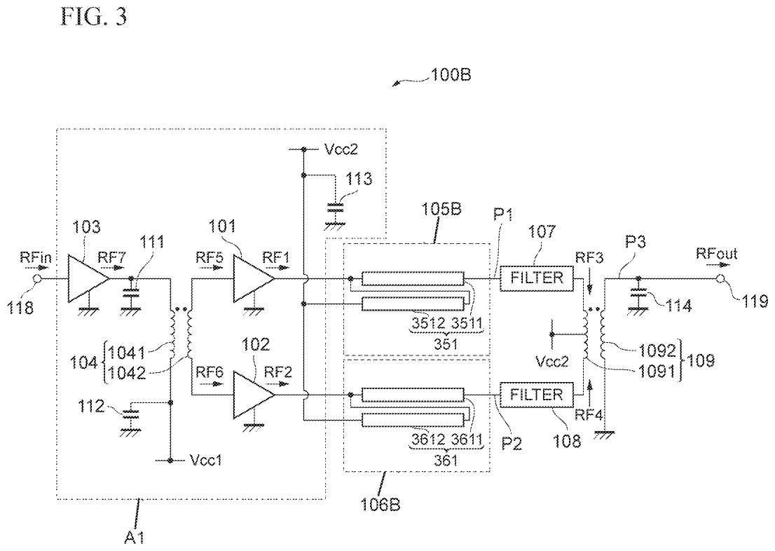

The matching circuit 105A and the matching circuit 106A may also be a matching circuit 105B including a transmission line transformer 351 and a matching circuit 106B including a transmission line transformer 361 as illustrated in the circuit diagram of a power amplifier circuit 100B in FIG. 3.

The transmission line transformer 351 includes a transmission line 3511 having one end connected to the output of the amplifier 101 and the other end connected to the input of the filter 107, and a transmission line 3512 having one end to which the power supply voltage Vcc2 is applied and the other end connected between the output of the amplifier 101 and one end of the transmission line 3511.

The transmission line transformer 361 includes a transmission line 3611 having one end connected to the output of the amplifier 102 and the other end connected to the input of the filter 108, and a transmission line 3612 having one end to which the power supply voltage Vcc2 is applied and the other end connected between the output of the amplifier 102 and one end of the transmission line 3611.

By the transmission line transformer 351, the impedance between the output of the amplifier 101 and the input of the filter 107 can be adjusted. By the transmission line transformer 361, the impedance between the output of the amplifier 102 and the input of the filter 108 can be adjusted. The impedance may also be adjusted by an autotransformer using an inductor instead of the transmission line.

The power amplifier circuit 100B can supply the same direct-current voltage to the input and the output of each of the filters 107 and 108, as per the power amplifier circuit 100A. Accordingly, it is possible to suppress the occurrence of a difference in direct-current voltage between the inputs and the outputs of the filters 107 and 108 and improve the power handling capability.

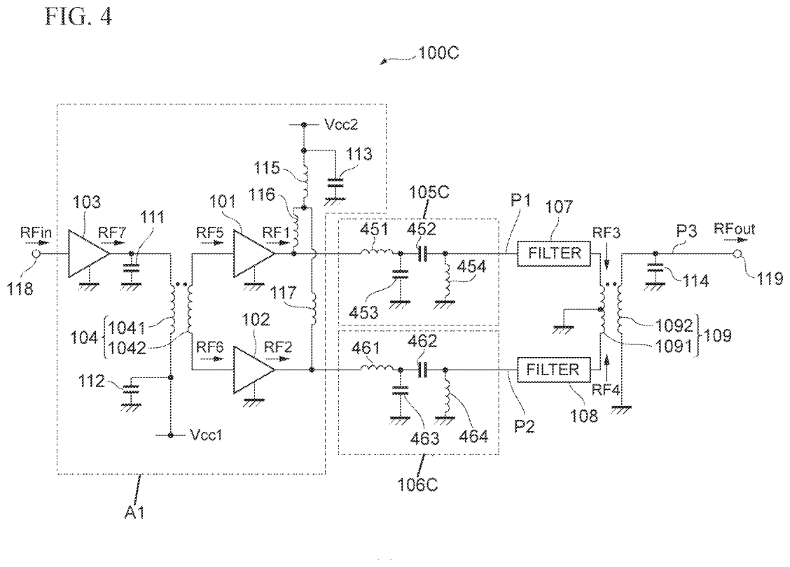

A third embodiment will be described. FIG. 4 illustrates a circuit diagram of a power amplifier circuit 100C according to the third embodiment.

In the power amplifier circuit 100C, the configurations of the matching circuit 105 and the matching circuit 106 are specifically illustrated as a matching circuit 105C (third matching circuit) and a matching circuit 106C (fourth matching circuit).

The matching circuit 105C includes inductors 451 and 454 and capacitors 452 and 453. The inductor 451 and the capacitor 452 are provided in series to the signal path P1 between the output of the amplifier 101 and the input of the filter 107. The capacitor 453 has one end connected between the inductor 451 and the capacitor 452, and the other end connected to the ground. The inductor 454 has one end connected between the capacitor 452 and the input of the filter 107, and the other end connected to the ground.

In the matching circuit 105B, the filter 107 is grounded through the inductor 454 in a direct-current manner. Accordingly, a reference voltage by the ground is supplied to the input of the filter 107.

The matching circuit 106B includes inductors 461 and 464 and capacitors 462 and 463. The matching circuit 106B is provided in the signal path P2 in the same manner as the matching circuit 105B being provided in the signal path P1. The reference voltage by the ground is supplied to the input of the filter 108.

In the power amplifier circuit 100B, the primary winding 1091 is connected to the ground. The primary winding 1091 is connected to the ground, such as being connected to the ground from the midpoint of the primary winding 1091. The output of the filter 107 and the output of the filter 108 are connected to the ground through the primary winding 1091, and the reference voltage is supplied from the ground.

Also in the power amplifier circuit 100B, as in the power amplifier circuit 100A, it is possible to suppress the occurrence of a difference in direct-current voltage between the inputs and the outputs of the filters 107 and 108 and improve the power handling capability.

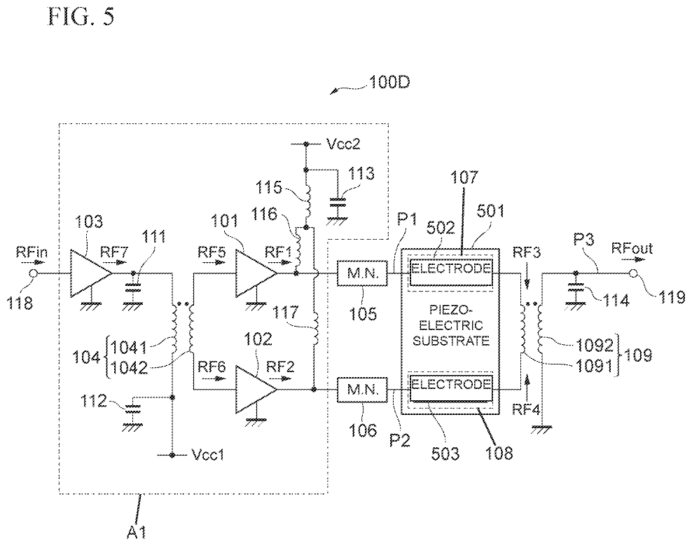

A fourth embodiment will be described. FIG. 5 illustrates a circuit diagram of a power amplifier circuit 100D according to the fourth embodiment. In the power amplifier circuit 100D, the filters 107 and 108 in the first embodiment are configured as acoustic wave filters. Specifically, in the power amplifier circuit 100D, an electrode 502 (first electrode) and an electrode 503 (second electrode) are provided on a piezoelectric substrate 501, and thus, the filters 107 and 108 are respectively configured.

For example, if the filters 107 are 108 are SAW filters, the electrodes 502 and 503 are provided on one surface of the piezoelectric substrate 501. Alternatively, if the filters 107 are 108 are BAW filters, the electrodes 502 and 503 are provided so as to sandwich the piezoelectric substrate 501. The piezoelectric substrate 501 and the electrode 502 constitute the filter 107, and the piezoelectric substrate 501 and the electrode 503 constitute the filter 108.

In the power amplifier circuit 100D, the electrode 502 and the electrode 503 are provided on the same piezoelectric substrate 501. Accordingly, the characteristics of the filter 107 and the filter 108 can be made uniform by making variations in the characteristics of the filter 107 and the filter 108, which occur at the time of manufacturing, similar to each other. Thus, since the operations of the filter 107 and the filter 108 are the same, it is possible to reduce the loss when the transformer 109 combines the signals.

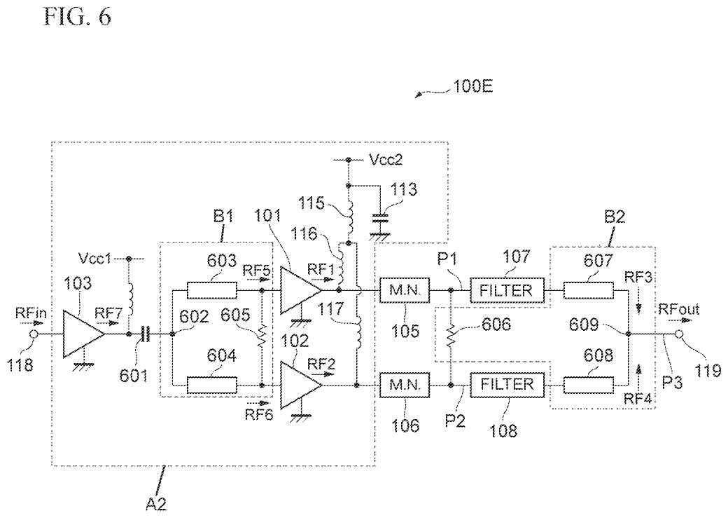

A fifth embodiment will be described. FIG. 6 illustrates a circuit diagram of a power amplifier circuit 100E according to the fifth embodiment. The power amplifier circuit 100E is different from the power amplifier circuit 100 in the configuration for dividing the signal from the amplifier 103 to the amplifiers 101 and 102 and the configuration for combining the signals from the amplifiers 101 and 102.

The power amplifier circuit 100E includes a capacitor 601, transmission lines 603, 604, 607, and 608, and resistors 605 and 606.

The capacitor 601 has one end connected to the output of the amplifier 103, and the other end connected to a branch point 602. The capacitor 601 has a function of cutting off direct current components of the signal RF7 from the amplifier 103.

The transmission line 603 (first transmission line) is provided in the signal path P1 with one end connected to the branch point 602 and the other end connected to the input of the amplifier 101. The transmission line 604 (second transmission line) is provided in the signal path P2 with one end connected to the branch point 602 and the other end connected to the input of the amplifier 102. Each of the transmission lines 603 and 604 is provided as a A/4 line with the wavelength of a signal in a predetermined band as A.

The resistor 605 has one end connected between the other end of the transmission line 603 and the input of the amplifier 101, and the other end connected between the other end of the transmission line 604 and the input of the amplifier 102.

The transmission lines 603 and 604 and the resistor 605 constitute a Wilkinson divider. By the transmission lines 603 and 604 and the resistor 605, a signal based on the signal RF7 from the amplifier 103 is divided into the signal RF5 and the signal RF6. The signal RF5 and the signal RF6 are in phase with each other. The transmission lines 603 and 604 and the resistor 605 function as a signal dividing unit B1. In the power amplifier circuit 100D, the transformer 104 of the amplifier unit A1 in the power amplifier circuit 100 is replaced with the signal dividing unit B1, and thus, an amplifier unit A2 is configured.

The resistor 606 has one end connected between the matching circuit 105 and the filter 107, and the other end connected between the matching circuit 106 and the filter 108.

The transmission line 607 is provided in the signal path P1 with one end connected to the output of the filter 107 and the other end connected to a merging point 609. The transmission line 608 is provided in the signal path P2 with one end connected to the output of the filter 108 and the other end connected to the merging point 609. Each of the transmission lines 607 and 608 is provided as a A/4 line. Note that the resistor 606 may be connected between a node between the matching circuit 105 and the amplifier 101 and a node between the matching circuit 106 and the amplifier 102. In addition, the resistor 606 may be connected between a node between the filter 107 and the transmission line 607 and a node between the filter 108 and the transmission line 608.

The resistor 606 and the transmission lines 607 and 608 constitute a Wilkinson coupler. The resistor 606 and the transmission lines 607 and 608 combine the signal RF3 from the filter 107 and the signal RF4 from the filter 108, and the output signal RFout is output from the output end 119 through the signal path P3. The resistor 606 and the transmission lines 607 and 608 function as a signal output unit B2.

Also in the power amplifier circuit 100E, the power of the signal filtered by the filters 107 and 108 is about half of the power of the output signal RFout. Accordingly, in the power amplifier circuit 100E, as in the power amplifier circuit 100, it is possible to improve the power handling capability required for the filters while increasing the power of the output signal RFout.

Note that two capacitors for cutting off direct-current components may be provided in the signal path P1 and the signal path P2 so as to be connected in series to the transmission line 603 and the transmission line 604. In addition, a matching circuit may be provided between the output of the amplifier 103 and the inputs of the amplifier 101 and the amplifier 102.

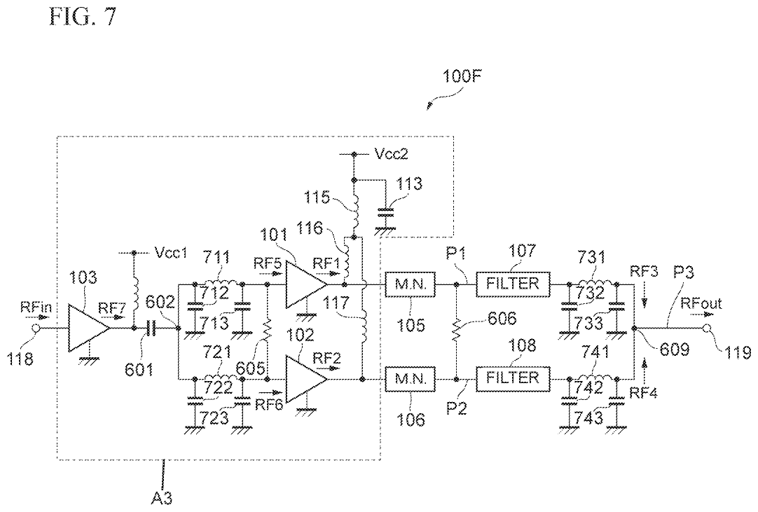

FIG. 7 illustrates a circuit diagram of a power amplifier circuit 100F in a case where the transmission lines 603, 604, 607, and 608 are constituted by circuits including inductors and capacitors in the power amplifier circuit 100E. The transmission line 603 is replaced with an inductor 711 connected in series along the signal path P1 and capacitors 712 and 713 provided to respectively connect one end and the other end of the inductor 711 to the ground. The transmission lines 604, 607, and 608 are likewise replaced with inductors 721, 731, and 741 and capacitors 722, 723, 732, 733, 742, and 743. Also in the power amplifier circuit 100F, it is possible to improve the power handling capability required for the filters while increasing the power of the output signal RFout.

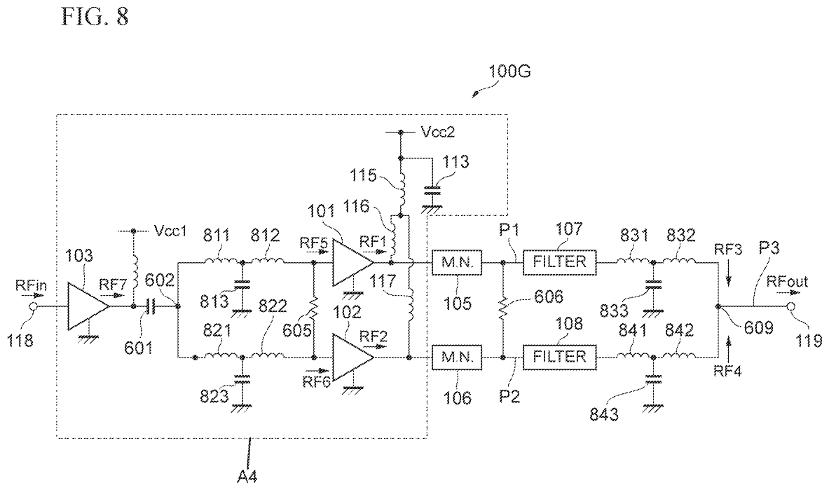

FIG. 8 illustrates a circuit diagram of a power amplifier circuit 100G in a case where the transmission lines 603, 604, 607, and 608 are constituted by circuits including inductors and capacitors in the power amplifier circuit 100E. The transmission line 603 is replaced with inductors 811 and 812 connected in series along the signal path P1 and a capacitor 813 provided to connect a node between the inductor 811 and the inductor 812 to the ground. The transmission lines 604, 607, and 608 are likewise replaced with inductors 821, 822, 831, 832, 841, and 842 and capacitors 823, 833, and 843. Also in the power amplifier circuit 100G, it is possible to improve the power handling capability required for the filters while increasing the power of the output signal RFout.

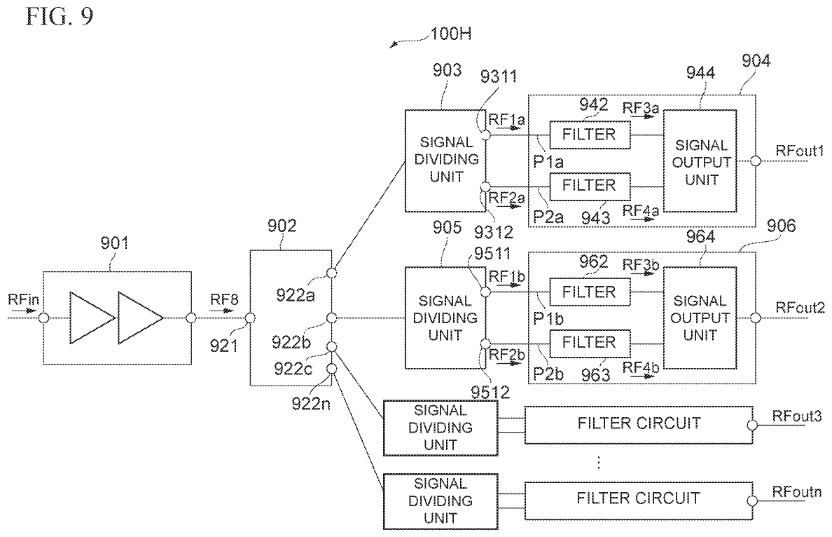

A sixth embodiment will be described. FIG. 9 illustrates a circuit diagram of a power amplifier circuit 100H. The power amplifier circuit 100H includes an amplifier circuit 901, a switch 902, signal dividing units 903 and 905, and filter circuits 904 and 906.

The amplifier circuit 901 is an amplifier circuit that amplifies the input signal RFin and outputs a signal RF8. The amplifier circuit 901 includes, for example, a plurality of amplifiers.

The switch 902 has an input end 921 and a plurality of output ends including output ends 922a (first output end), 922b (second output end), 922c, and 922n. Based on an external control signal, the switch 902 switches the connection between the input end 921 and one of the output ends 922a to 922n according to the frequency band of the signal RF8.

The signal dividing unit 903 (first signal dividing unit) has an input connected to the output end 922a (first output end). If the frequency band of the signal RF8 is a certain frequency band (frequency band A), the signal RF8 is input to the signal dividing unit 903 via the switch 902.

Based on the signal RF8 in the frequency band A, the signal dividing unit 903 outputs a signal RF1a via a dividing terminal 9311 (first dividing terminal) and outputs a signal RF2a via a dividing terminal 9312 (second dividing terminal). That is, based on the signal RF8 in the frequency band A, the signal dividing unit 903 outputs the signals RF1a and RF2a in the frequency band A to signal paths Pla and P2a, respectively.

The filter circuit 904 (first filter circuit) includes filters 942 and 943 and a signal output unit 944 (first signal output unit). The filter 942 is provided in the signal path Pla. The filter 943 is provided in the signal path P2a. The filter 942 is connected to the dividing terminal 9311, and filters the signal RF1a input from the signal dividing unit 903. The filter 943 is connected to the dividing terminal 9312, and filters the signal RF2a input from the signal dividing unit 903.

The signal output unit 944 is connected to the output of the filter 942 and the output of the filter 943. The signal output unit 944 outputs an output signal RFout1 based on a signal RF3a output from the filter 942 and a signal RF4a output from the filter 943.

The signal dividing unit 905 (second signal dividing unit) has an input connected to the output end 922b (second output end). If the frequency band of the signal RF8 is a frequency band (frequency band B) different from the frequency band A, the signal RF8 is input to the signal dividing unit 905 via the switch 902.

Based on the signal RF8 in the frequency band B, the signal dividing unit 905 outputs a signal RF1b via a dividing terminal 9511 (third dividing terminal) and outputs a signal RF2b via a dividing terminal 9512 (fourth dividing terminal). That is, the signal dividing unit 905 outputs the signals RF1b and RF2b in the frequency band B to signal paths P1b and P2b, respectively.

The filter circuit 906 (second filter circuit) includes filters 962 and 963 and a signal output unit 964 (second signal output unit). As in the filter circuit 904, the filter circuit 906 outputs a signal RFout2 in the frequency band B.

In the power amplifier circuit 100H, a signal dividing unit and a filter circuit can be provided for each frequency band. Accordingly, even in a case of supporting a plurality of frequency bands, the power of the signal filtered by each filter circuit is about half the power of each output signal. Accordingly, in the power amplifier circuit 100H, even in a case of supporting a plurality of frequency bands, it is possible to improve the power handling capability required for a filter while increasing the power of an output signal. Note that the number of filter circuits and the number of output ends of the switch 902 are not limited to two, and a plurality of filter circuits and output ends may be provided corresponding to a plurality of frequency bands. In addition, the configurations described in the above embodiments may be used for the signal dividing unit and the signal output unit.

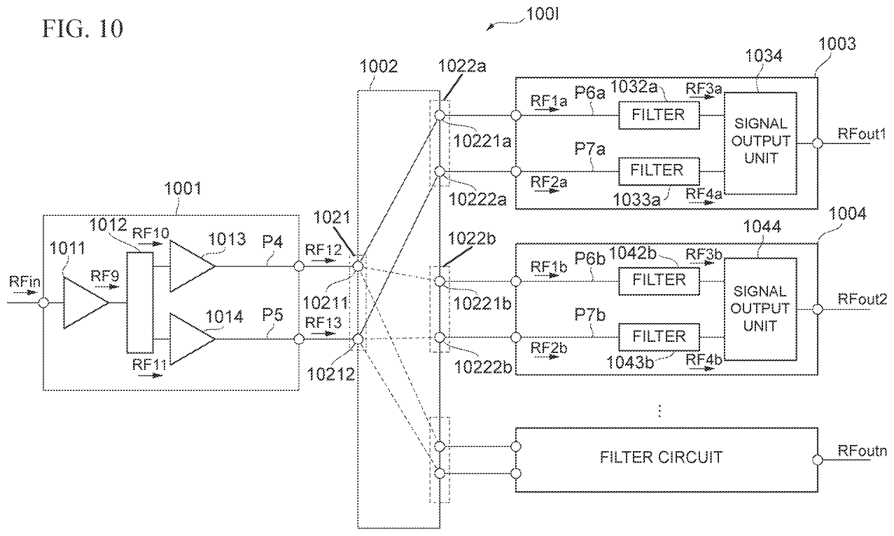

A seventh embodiment will be described. FIG. 10 illustrates a circuit diagram of a power amplifier circuit 100I according to the seventh embodiment.

The power amplifier circuit 100I includes an amplifier circuit 1001, a switch 1002, and filter circuits 1003 and 1004.

The amplifier circuit 1001 includes amplifiers 1011 (first amplifier), 1013, and 1014 and a signal dividing unit 1012 (signal dividing unit). The amplifier 1011 outputs a signal RF9 obtained by amplifying the input signal RFin to the signal dividing unit 1012.

Based on the signal RF9 from the amplifier 1011, the signal dividing unit 1012 outputs a signal RF10 to a signal path P4 (first signal path) and a signal RF11 to a signal path P5 (second signal path).

The amplifier 1013 is provided in the signal path P4, amplifies the signal RF10, and outputs a signal RF12. The amplifier 1014 is provided in the signal path P5, amplifies the signal RF11, and outputs a signal RF13.

The switch 1002 has an input end portion 1021, an output end portion 1022a (first output end portion), and an output end portion 1022b (second output end portion). The input end portion 1021 has an input end 10211 connected to the signal path P4 and an input end 10212 connected to the signal path P5. The output end portion 1022a has an output end 10221a and an output end 10222a. The output end portion 1022b has an output end 10221b and an output end 10222b.

The input end portion 1021 is connected to the output end portion 1022a or 1022b according to the frequency band of the signal RFin. More specifically, the input end 10211 is connected to the output end 10221a or the output end 10221b according to the frequency band of the signal RFin. The input end 10212 is connected to the output end 10222a or 10222b according to the frequency band of the signal RF9.

If the frequency band of the signal RFin is a certain frequency band (frequency band A), the switch 1002 connects the input end portion 1021 and the output end portion 1022a to each other. If the frequency band of the signal RFin is a frequency band (frequency band B) different from the frequency band A, the switch 1002 connects the input end portion 1021 and the output end portion 1022b to each other.

The filter circuit 1003 includes filters 1032a and 1033a and a signal output unit 1034. The filter 1032a is connected to the output end 10221a. The filter 1032a is provided in a signal path P6a and filters the signal RF1a input from the amplifier 1013 through the output end 10221a. The filter 1032a is connected to the output end 10222a. The filter 1033a is provided in a signal path P7a and filters the signal RF2a input from the amplifier 1014 through the output end 10222a. The signals RF1a and RF2a are signals RF12 and RF13, respectively, in the frequency band A.

To amplify a signal in the frequency band A, the signal RF1a is input to the filter 1032a through the signal path P4, the switch 1002, and the signal path P6a. That is, the signal path P4, the switch 1002, and the signal path P6a constitute one signal path. Likewise, the signal RF2a is input to the filter 1033a through the signal path P5, the switch 1002, and the signal path P7a. That is, the signal path P5, the switch 1002, and the signal path P7a constitute one signal path.

The signal output unit 1034 is connected to the output of the filter 1032a and the output of the filter 1033a. The signal output unit 1034 outputs the output signal RFout1 based on the signal RF3a output from the filter 1032a and the signal RF4a output from the filter 1033a.

The filter circuit 1004 includes filters 1042b and 1043b and a signal output unit 1044. The filter 1042b is connected to the output end 10221b. The filter 1043b is connected to the output end 10222b. The signal RF1b in the frequency band B is input to the filter 1042b through a signal path constituted by the signal path P4, the switch 1002, and a signal path P6b. The signal RF2b in the frequency band B is input to the filter 1043b through a signal path constituted by the signal path P4, the switch 1002, and a signal path P7b. The signals RF1b and RF2b are signals RF12 and RF13, respectively, in the frequency band B. As in the filter circuit 1003, the filter circuit 1004 outputs the signal RFout2 in the frequency band B.

Also in the power amplifier circuit 100I, a signal dividing unit and a filter circuit can be provided for each frequency band. Accordingly, in the power amplifier circuit 100I, as in the power amplifier circuit 100H, it is possible to improve the power handling capability required for a filter while increasing the power of an output signal, even in a case of supporting a plurality of frequency bands. In addition, by transmitting a signal in the form of a differential signal, it is possible to reduce jumping or leaking of a signal to another circuit.

Note that the number of filter circuits 1003 and 1004 and the number of output ends are not limited to two, and a plurality of filter circuits and output ends may be provided corresponding to a plurality of frequency bands. In addition, the configurations described in the above embodiments may be used for the signal dividing unit and the signal output unit. Furthermore, a signal amplified by the amplifier 1011 may be divided and input to the input end portion 1021 without necessarily using the amplifiers 1013 and 1014.

The exemplary embodiments of the present disclosure have been described above. The power amplifier circuit 100 includes: the amplifier unit A1 that amplifies the input signal RFin of the time division duplex scheme and outputs the signal RF1 to the signal path P1 and the signal RF2 to the signal path P2; the filter 107 that is provided in the signal path P1 and outputs the signal RF3 based on the signal RF1; the filter 108 that is provided in the signal path P2 and outputs the signal RF4 based on the signal RF2; and the transformer 109 that is connected to the signal path P1 through the filter 107 and connected to the signal path P2 through the filter 108 and outputs the output signal RFout based on the signal RF3 and the signal RF4 to the signal path P3.

In the power amplifier circuit 100, the signals RF1 and RF2 whose power is about half of the power of the signal RFout can be filtered by the filters 107 and 108, respectively. Since the power handling capability required for the filters 107 and 108 is relaxed as compared with a case where the output signal RFout is filtered, the power of the output signal RFout can be increased. Accordingly, it is possible to improve the power handling capability required for the filters while increasing the output power.

In addition, in the power amplifier circuit 100, the amplifier unit A1 includes: the amplifier 101 that is provided in the signal path P1 and outputs the signal RF1 based on the signal RF5; the amplifier 102 that is provided in the signal path P2 and outputs the signal RF2 based on the signal RF6; the amplifier 103 that amplifies the input signal RFin and outputs the signal RF7; and the transformer 104 that is connected to the output of the amplifier 103 and outputs, based on the signal RF7, the signal RF5 to the signal path P1, and the signal RF6 to the signal path P2.

In addition, in the power amplifier circuit 100, the transformer 104 includes: the primary winding 1041 having one end connected to the output of the amplifier 103 and the other end supplied with the power supply voltage Vcc1 of the amplifier 103; and the secondary winding 1042 having one end connected to the input of the amplifier 101 and the other end connected to the input of the amplifier 102, the secondary winding 1042 being electromagnetically coupled to the primary winding 1041, and the transformer 109 includes: the primary winding 1091 having one end connected to the output of the amplifier 101 and the other end connected to the output of the amplifier 102; and the secondary winding 1092 having one end connected to the output end and the other end connected to the ground, the secondary winding 1092 being electromagnetically coupled to the primary winding 1091.

The transformer 104 transforms the signal RF7, which is an unbalanced signal, into the signal RF5 and the signal RF6, which are balanced signals. By amplifying the balanced signals and combining them by using the transformer 109, it is possible to improve the power handling capability required for the filters while increasing the power of the output signal RFout.

In addition, the power amplifier circuit 100A further includes: the matching circuit 105A that is provided between the amplifier 101 and the filter 107 and supplies the power supply voltage Vcc2 to the input of the filter 107; and the matching circuit 106A that is provided between the amplifier 102 and the filter 108 and supplies the power supply voltage Vcc2 to the input of the filter 108. The power supply voltage Vcc2 is supplied to the output of the filter 107 and the output of the filter 108 through the primary winding 1091.

By supplying the power supply voltage Vcc2 to the outputs of the filters 107 and 108 through the primary winding 1091, it is possible to prevent a difference in direct-current voltage from occurring between the inputs and the outputs of the filters 107 and 108. By supplying substantially the same power supply voltage Vcc2 to the inputs and the outputs of the filters 107 and 108 in the power amplifier circuit 100A, it is possible to suppress the occurrence of a difference in direct-current voltage between the inputs and the outputs of the filters 107 and 108 and improve the power handling capability.

In addition, the power amplifier circuit 100C further includes: the matching circuit 105C that is provided in the signal path P1 and connects the input of the filter 107 to the ground in a direct-current manner; and the matching circuit 106C that is provided in the signal path P2 and connects the input of the filter 108 to the ground in a direct-current manner. The output of the filter 107 and the output of the filter 108 are connected to the ground through the primary winding 1091.

In the power amplifier circuit 100C, the output of the filter 107 and the output of the filter 108 are connected to the ground through the primary winding 1091, and the reference voltage is supplied from the ground. Also in the power amplifier circuit 100C, it is possible to suppress the occurrence of a difference in direct-current voltage between the inputs and the outputs of the filters 107 and 108 and improve the power handling capability.

In addition, in the power amplifier circuits 100, 100A, 100B, and 100C, the transformer 104 outputs the signal RF5 and the signal RF6 such that the phases of the signal RF5 and the signal RF6 are opposite to each other. Accordingly, as differential configurations, the amplifiers 101 and 102 can amplify the signal RF5 and the signal RF6 to increase the output power of the output signal RFout.

In addition, in the power amplifier circuits 100E, 100F, and 100G, the signal dividing unit B1 outputs the signal RF5 and the signal RF6 such that the signal RF5 and the signal RF6 are in phase with each other.

Accordingly, the signal RF5 and the signal RF6, which are in-phase signals, can be amplified, and the output power of the output signal RFout can be increased.

In addition, in the power amplifier circuit 100E, the signal dividing unit B1 includes: the transmission line 603 provided in the signal path P1; and the transmission line 604 provided in the signal path P2. Accordingly, it is possible to output the signal RF5 and the signal RF6, which are in-phase signals, with a simple configuration.

In addition, in the power amplifier circuit 100D, the filter 107 is constituted by the piezoelectric substrate 501 and the electrode 502 provided on the piezoelectric substrate 501, and the filter 108 is constituted by the piezoelectric substrate 501 and the electrode 503 provided on the piezoelectric substrate 501. Accordingly, it is possible to suppress a difference in characteristics due to variations in characteristics that occur at the time of manufacturing the filters 107 and 108. Accordingly, since the operations of the filter 107 and the filter 108 can be made the same, it is possible to reduce the loss when the transformer 109 combines the signals.

In addition, the power amplifier circuit 100H includes the amplifier circuit 901 that amplifies the input signal RFin and outputs the signal RF8. The power amplifier circuit 100H includes the switch 902 that has the input end 921 connected to the output of the amplifier circuit 901, the output end 922a, and the output end 922b, connects the input end 921 and the output end 922a if the signal RF8 is in the frequency band A, connects the input end 921 and the output end 922b if the signal RF8 is in the frequency band B, and switches the connection between the input end 921 and the output end 922a or the output end 922b.

In addition, the power amplifier circuit 100H includes: the signal dividing unit 903 that is connected to the output end 922a, outputs the signal RF1a based on the signal RF8 through the dividing terminal 9311, and outputs the signal RF2a based on the signal RF8 through the dividing terminal 9312; and the signal dividing unit 905 that is connected to the output end 922b, outputs the signal RF1b based on the signal RF8 through the dividing terminal 9511, and outputs the signal RF2b based on the signal RF8 through the dividing terminal 9512.

In addition, the power amplifier circuit 100H includes: the filter circuit 904 connected to the signal dividing unit 903; and the filter circuit 906 connected to the signal dividing unit 905. The filter circuit 904 includes: the filter 942 that is connected to the dividing terminal 9311 and outputs the signal RF3a based on the signal RF1a; and the filter 943 that is connected to the dividing terminal 9312 and outputs the signal RF4a based on the signal RF2a. The filter circuit 906 includes: the filter 962 that is connected to the dividing terminal 9511 and outputs a signal RF3b based on the signal RF1b; and the filter 963 that is connected to the dividing terminal 9512 and outputs a signal RF4b based on the signal RF2b.

By the power amplifier circuit 100H, it is possible to improve the power handling capability required for the filters while increasing the power of the output signal RFout to support a plurality of frequency bands.

In addition, the power amplifier circuit 100I includes the amplifier circuit 1001 that outputs, to the signal path P4, the signal RF12 obtained by amplifying the input signal RFin and outputs, to the signal path P5, the signal RF13 obtained by amplifying the input signal RFin.

In addition, the power amplifier circuit 100I includes the switch 1002 including: the input end portion 1021 having the input end 10211 connected to the signal path P4 and the input end 10212 connected to the signal path P5; the output end portion 1022a having the output end 10221a and the output end 10222a; and the output end portion 1022b having the output end 10221b and the output end 10222b. The switch 1002 includes: the switch that connects the input end portion 1021 and the output end portion 1022a if the signal RF10 is in the first frequency band, and connects the input end portion 1021 and the output end portion 1022b if the first signal is in the second frequency band; the filter circuit 1003 connected to the output end portion 1022a; and the filter circuit 1004 connected to the output end portion 1022b.

The filter circuit 1003 includes: the filter 1032a that is connected to the output end 10221a and outputs the signal RF3a based on the signal RF1a; the filter 1033a that is connected to the output end 10222a and outputs the signal RF4a based on the signal RF2a; and the signal output unit 1034 that outputs the output signal RFout1 based on the signal RF3a and the signal RF4a.

The filter circuit 1004 includes: the filter 1042b that is connected to the output end 10221b and outputs the signal RF3b based on the signal RF1b; the filter 1043b that is connected to the output end 10222b and outputs the signal RF4b based on the signal RF2b; and the signal output unit 1044 that outputs the output signal RFout2 based on the signal RF3b and the signal RF4b.

Also in the power amplifier circuit 100I, it is possible to improve the power handling capability required for the filters while increasing the power of the output signal RFout to support a plurality of frequency bands.

In addition, in the power amplifier circuit 100I, the amplifier circuit 1001 includes: the amplifier 1011 that amplifies the input signal RFin; and the signal dividing unit 1012 that is connected to the output of the amplifier 1011, and outputs, based on the signal RF9 from the amplifier 1011, the signal RF10 to the signal path P4 and the signal RF11 to the signal path P5. Accordingly, it is possible to filter a balanced signal through the switch 1002 and the corresponding filter circuit.

In addition, in the power amplifier circuit 100I, the amplifier circuit 1001 outputs the signal RF12 and the signal RF13 such that the phases of the signal RF12 and the signal RF13 are opposite to each other. Accordingly, by differential amplification, the power amplifier circuit 100I can improve the power handling capability required for each filter while increasing the output power.

As an additional embodiment, an eighth embodiment will be described. In addition to the case where the TDD scheme is used as described above, it is sometimes required in an FDD (Frequency Division Duplex) scheme to improve the power handling capability required for a filter while increasing the output power.

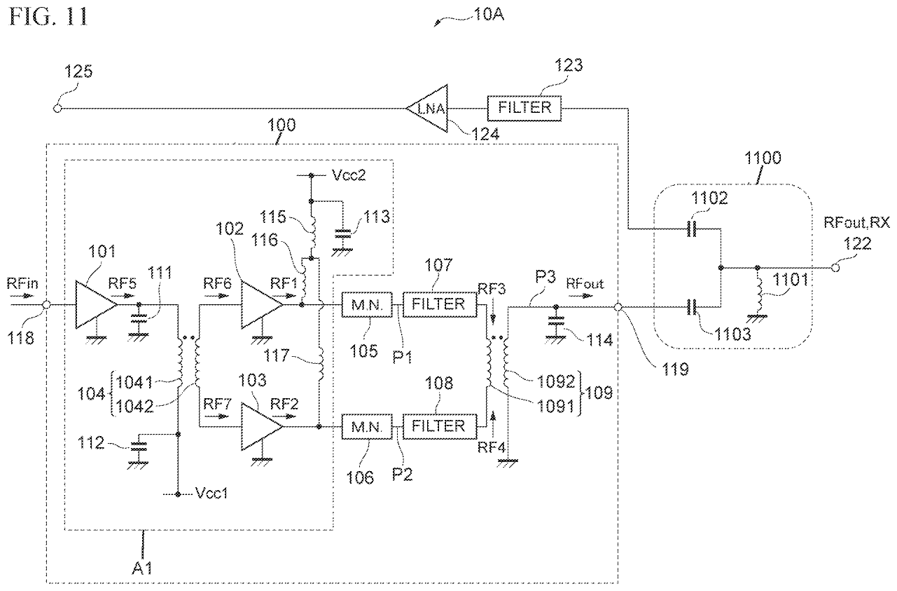

FIG. 11 illustrates a circuit diagram of a communication module (communication device) 10A that performs communication in the FDD scheme. The communication module 10A includes the power amplifier circuit 100 that is substantially the same as that of the communication module 10. The communication module 10A is different from the communication module 10 in that the communication module 10A does not include the switch 121 in the communication module 10 and includes a signal transmission/reception unit 1100.

The signal transmission/reception unit 1100 is connected to the output end 119 of the power amplifier circuit 100, the low noise amplifier 124, and the antenna terminal 122 (transmission/reception terminal). The signal transmission/reception unit 1100 outputs the output signal RFout to the antenna terminal 122, and receives the reception signal from the antenna terminal 122.

The signal transmission/reception unit 1100 includes an inductor 1101 and capacitors 1102 and 1103. The inductor 1101 has one end connected to the antenna terminal 122 and the other end connected to the ground. The capacitor 1102 has one end connected to the low noise amplifier 124 (reception signal amplifier) through the filter 123, and the other end connected to the antenna terminal 122. The capacitor 1103 has one end connected to the output end 119, and the other end connected to the antenna terminal 122.

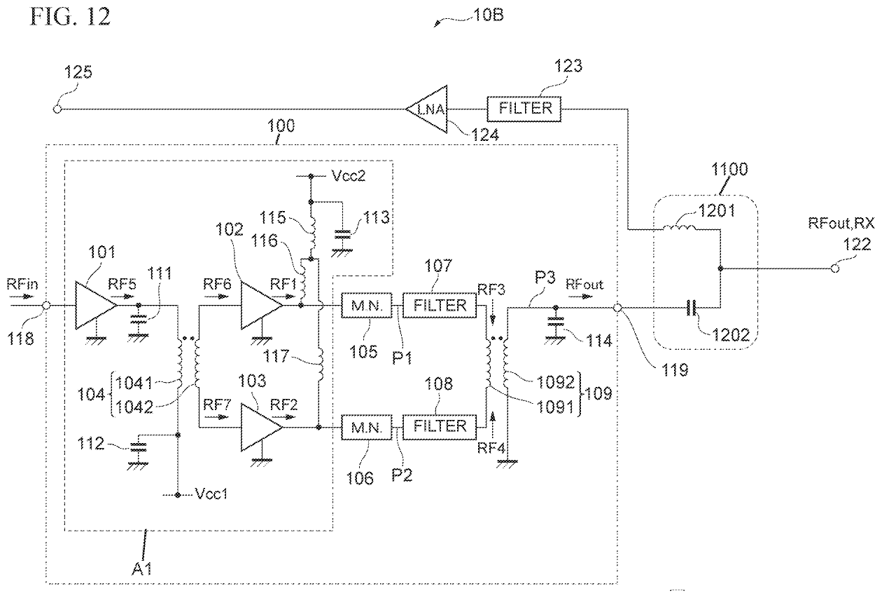

By using the inductor 1101 and the capacitors 1102 and 1103, the signal transmission/reception unit 1100 adjusts the impedances of the antenna terminal 122 and the low noise amplifier 124 as seen from the output end 119. In addition, by using the inductor 1101 and the capacitors 1102 and 1103, the signal transmission/reception unit 1100 adjusts the impedances of the low noise amplifier 124 and the output end 119 as seen from the antenna terminal 122. The inductor 1101 is an example of a “first impedance adjustment element” provided between the antenna terminal 122 and the power amplifier circuit 100 or a “second impedance adjustment element” provided between the antenna terminal 122 and the low noise amplifier 124. In addition, the capacitor 1102 is an example of the “first impedance adjustment element”, and the capacitor 1103 is an example of the “second impedance adjustment element”. Note that the first and second impedance adjustment elements are not limited to the elements disclosed in FIG. 11 and FIG. 12 to be given later, and may be passive elements, such as an inductor, a capacitor, and a resistor, or a combined circuit thereof.

In the frequency band of the output signal RFout, the signal transmission/reception unit 1100 adjusts the impedance of the antenna terminal 122 as seen from the output end 119 to be short-circuited, and the impedance of the low noise amplifier 124 as seen from the output end 119 to be open-circuited. In the frequency band of the reception signal Rx, the signal transmission/reception unit 1100 adjusts the impedance of the low noise amplifier 124 as seen from the antenna terminal 122 to be short-circuited, and the impedance of the output end 119 as seen from the antenna terminal 122 to be open-circuited. Accordingly, it is possible to suppress the output signal RFout from flowing into the low noise amplifier 124 and the reception signal Rx from flowing into the output end 119.

In the power amplifier circuit 100, it is possible to improve the power handling capability required for the filters while increasing the power of the output signal RFout. Therefore, also in the communication module 10A that performs communication in the FDD scheme, it is possible to improve the power handling capability while increasing the power of the output signal RFout.

FIG. 12 illustrates a circuit diagram of a communication module 10B that performs communication in the FDD scheme.

The communication module 10B is different from the communication module 10A in that the communication module 10B includes a signal transmission/reception unit 1200. The signal transmission/reception unit 1200 includes an inductor 1201 and a capacitor 1202. The inductor 1201 has one end connected to the low noise amplifier 124 through the filter 123, and the other end connected to the antenna terminal 122. The capacitor 1202 has one end connected to the output end 119, and the other end connected to the antenna terminal 122. The inductor 1201 is an example of the “second impedance adjustment element” provided between the antenna terminal 122 and the low noise amplifier 124. In addition, the capacitor 1202 is an example of the “first impedance adjustment element” provided between the antenna terminal 122 and the power amplifier circuit 100. By using the inductor 1201 and the capacitor 1202, the signal transmission/reception unit 1200 adjusts the impedances of the low noise amplifier 124 and the output end 119 as seen from the antenna terminal 122. Also in the communication module 10B, as in the communication module 10A, it is possible to suppress the output signal RFout from flowing into the low noise amplifier 124 and the reception signal Rx from flowing into the output end 119. In addition, the communication module 10B includes the power amplifier circuit 100, and it is possible to improve the power handling capability while increasing power of the output signal RFout.

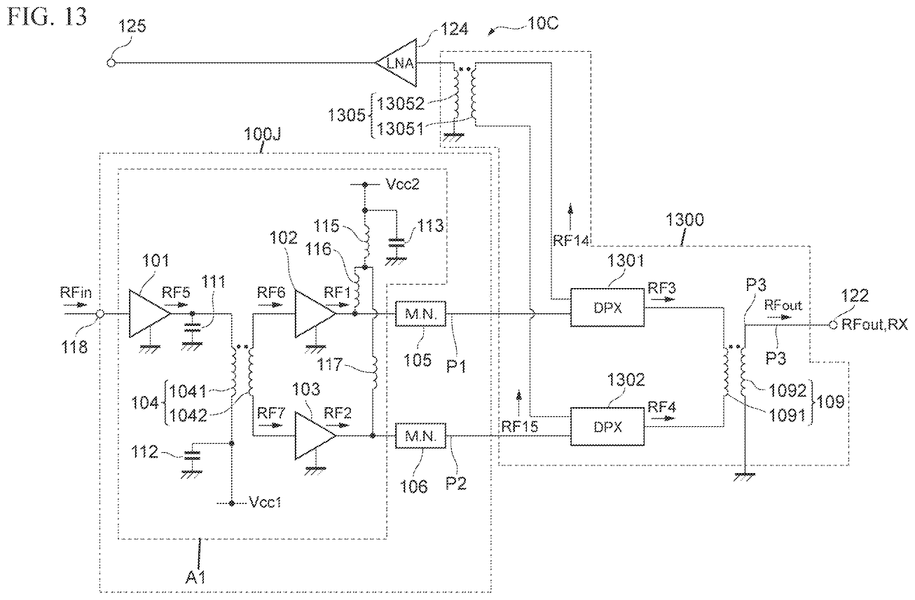

A ninth embodiment will be described. FIG. 13 illustrates a circuit diagram of a communication module 10C according to the ninth embodiment.

The communication module 10C is different from the communication module 10 in that the filters 107 and 108 in the communication module 10 are replaced with a duplexer 1301 and a duplexer 1302, and the signals RF14 and RF15 from the duplexers 1301 and 1302 are combined by a transformer 1305. The communication module 10C includes a power amplifier circuit 100J in which the power amplifier circuit 100 does not include the filters 107 and 108, instead of the power amplifier circuit 100 in the communication module 10.

The communication module 10C includes a signal transmission/reception unit 1300, and the signal transmission/reception unit 1300 includes the duplexers 1301 and 1302, the transformer 109, and the transformer 1305.

In the communication module 10C, the signal RF3 based on the signal RF1 is output from the duplexer 1301, and the signal RF4 based on the signal RF2 is output from the duplexer 1302. The signal RF3 and the signal RF4 are combined by the transformer 109, and the output signal RFout is output through the signal path P3.

In addition, in the communication module 10C, the reception signal Rx received through the antenna terminal 122 is divided by the transformer 109 and supplied to each of the duplexers 1301 and 1302. Based on the signal from the transformer 109, the signal RF14 (fifth signal) is output from the duplexer 1301, and the signal RF15 (sixth signal) is output from the duplexer 1302.

Each of the duplexers 1301 and 1302 has a filter characteristic that prevents the signals RF3 and RF4 from flowing into the transformer 1305 in the frequency band of the output signal RFout. Each of the duplexers 1301 and 1302 also has a filter characteristic that prevents the signals RF14 and RF15 from flowing into the amplifiers 102 and 103 in the frequency band of the reception signal Rx. In other words, each of the duplexers 1301 and 1302 has the same passband and stopband.

The signal RF14 and the signal RF15 are input to a primary winding 13051 of the transformer 1305. The filtered and combined reception signal is input to the low noise amplifier 124 through a secondary winding 13052 electromagnetically coupled to the primary winding 13051.

In the communication module 10C, the power of the signal filtered by the duplexers 1301 and 1302 is about half of the power of the output signal RFout. Therefore, the power handling capability of the duplexers 1301 and 1302 only needs to withstand half the power as compared to a case where the output signal RFout is filtered. That is, in the communication module 10C, it is possible to improve the power handling capability required for a filter while increasing the power of the output signal RFout.

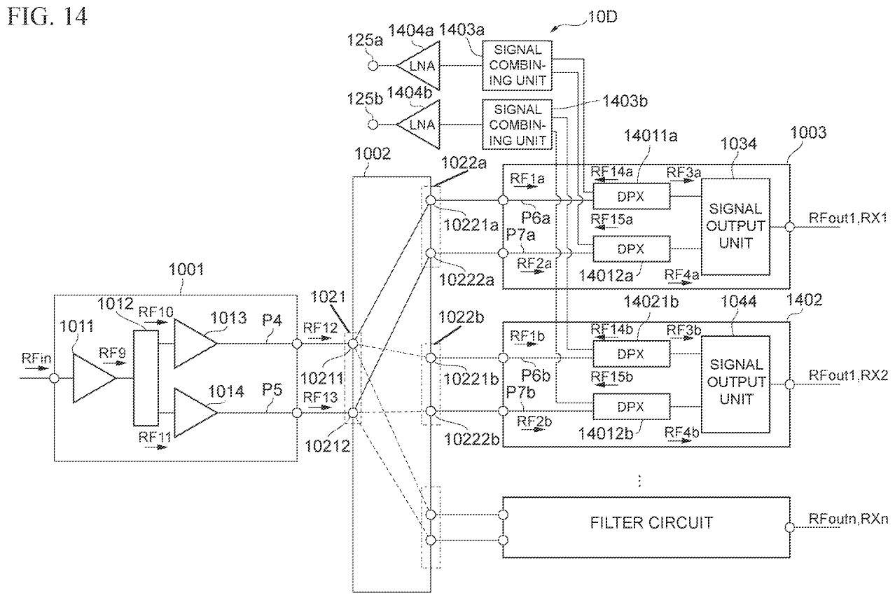

A tenth embodiment will be described. FIG. 14 illustrates a circuit diagram of a communication module 10D according to the tenth embodiment. The communication module 10D has a configuration in which the filter circuits 1003 and 1004 are replaced with filter circuits 1401 and 1402, respectively, and the filters 1032a, 1033a, 1042b, and 1043b are replaced with duplexers 14011a, 14012a, 14011b, and 14012b in the power amplifier circuit 100I described with reference to FIG. 10. In addition, the signal output units 1034 and 1044 in FIG. 14 correspond to the transformer 109 in FIG. 13.

The communication module 10D includes a signal combining unit 1403a connected to the duplexers 14011a and 14012a. Signals RF14a and RF15a based on a reception signal Rx1 are input to the signal combining unit 1403a through the duplexers 14011a and 14012a, and the signal RF14a and the signal RF15a are combined. The signal combining unit 1403a corresponds to, for example, the transformer 1305 in FIG. 13. The signal combining unit may include a power combining circuit (Power Combiner) in addition to the transformer. The communication module 10D includes a low noise amplifier 1405a (reception signal amplifier) connected to the signal combining unit 1403a. The low noise amplifier 1405a amplifies the signal from the signal combining unit 1403a and outputs the amplified signal to a terminal 125a.

The communication module 10D includes a signal combining unit 1403b connected to duplexers 14011b and 14012b. Signals RF14b and RF15b based on a reception signal Rx2 are input to the signal combining unit 1403b through the duplexers 14011b and 14012b, and the signal RF14b and the signal RF15b are combined. The communication module 10D includes a low noise amplifier 1405b (reception signal amplifier) connected to the signal combining unit 1403b. The low noise amplifier 1405b amplifies the signal from the signal combining unit 1403b and outputs the amplified signal to a terminal 125b. Note that a signal output unit is provided for each of the other filter circuits.

In the communication module 10D, as in the power amplifier circuit 100I, a signal dividing unit and a filter circuit can be provided for each frequency band. Accordingly, in the communication module 10D, as in the power amplifier circuit 100I, it is possible to improve the power handling capability required for a filter while increasing the power of an output signal, even in a case of supporting a plurality of frequency bands.

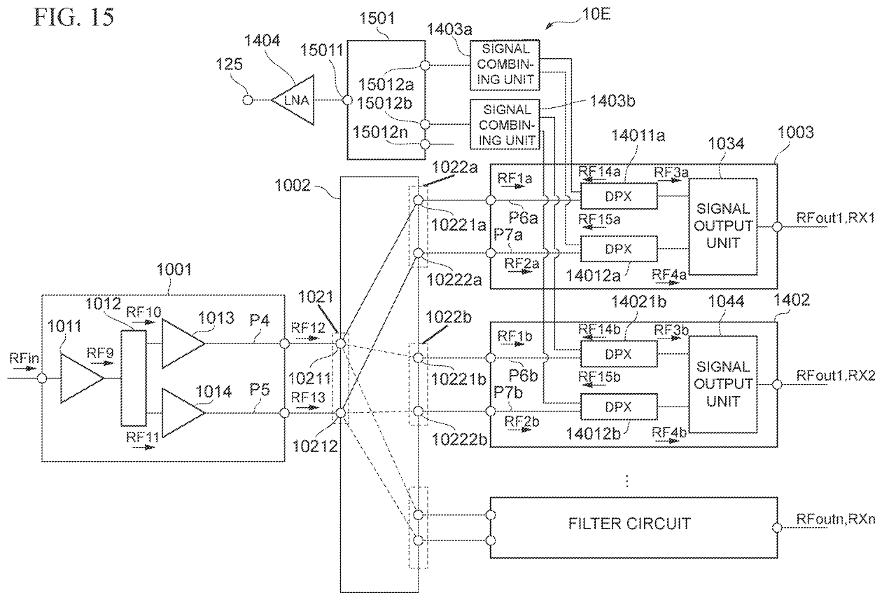

FIG. 15 illustrates a circuit diagram of a communication module 10E as another example. The communication module 10E includes a switch 1501 having input terminals 15012a, 15012b, . . . , and 15012n connected to respective signal output units and an output terminal 15011 connected to a low noise amplifier 1404. It is possible to improve the power handling capability required for a filter while increasing the power of an output signal, even in a case of supporting a plurality of frequency bands, by using the single lower noise amplifier 1404 by the switch 1501 that can be switched according to the frequency band as in the communication module 10E.

In the communication modules 10C, 10D, and 10E, the low noise amplifiers may be amplifiers having differential configurations to which high frequency signals having phases opposite to each other are input.

It should be noted that the embodiments described above are intended to facilitate understanding of the present disclosure, and are not intended to limit the present disclosure. The present disclosure can be modified/improved without necessarily departing from the gist thereof, and equivalents thereof are also included in the present disclosure. That is, those skilled in the art can modify the design of each embodiment as appropriate, and such modifications are also included in the scope of the present disclosure as long as they have the features of the present disclosure. For example, each element included in each embodiment and the arrangement, material, condition, shape, size, and the like thereof are not limited to those illustrated, and can be changed as appropriate. Each embodiment is an example, and it is needless to say that the configurations illustrated in different embodiments can be partly replaced or combined. These are also included in the scope of the present disclosure as long as they include the features of the present disclosure.

### REFERENCE SIGNS LIST

10, 10A, 10B, 10C, 10D, 10E communication module
100, 100A, 100B, 100C, 100D, 100E, 100F, 100G, 100H, 100I power amplifier circuit
101, 102, 103 amplifier
104, 109, 1305 transformer
105, 105A, 105B, 105C, 106, 106A, 106B, 106C matching circuit
107, 108 filter
501 piezoelectric substrate
502, 503 electrode
603, 604, 607, 608 transmission line
904, 906, 1003, 1004, 1401, 1402 filter circuit
1301, 1302 duplexer

1. A power amplifier circuit comprising:
an amplifier circuit that is configured to amplify an input signal of a time division duplex scheme, and to output a first signal to a first signal path and a second signal to a second signal path;
a first filter that is in the first signal path and that is configured to output a third signal based on the first signal;
a second filter that is in the second signal path and that is configured to output a fourth signal based on the second signal; and
a signal output that is connected to the first signal path through the first filter and connected to the second signal path through the second filter, and that is configured to output an output signal based on the third signal and the fourth signal to a third signal path.

2. The power amplifier circuit according to claim 1, wherein the amplifier circuit comprises:
a first amplifier that is in the first signal path and that is configured to output the first signal based on a fifth signal;
a second amplifier that is in the second signal path and that is configured to output the second signal based on a sixth signal;
a third amplifier that is configured to amplify the input signal and to output a seventh signal; and
a signal divider that is connected to an output of the third amplifier and that is configured to output, based on the seventh signal, the fifth signal to the first signal path, and the sixth signal to the second signal path.

3. The power amplifier circuit according to claim 2,
wherein the signal divider is a first transformer comprising:
a first primary winding having a first end connected to the output of the third amplifier and a second end supplied with a first power supply voltage of the third amplifier; and
a first secondary winding having a first end connected to an input of the first amplifier and a second end connected to an input of the second amplifier, the first secondary winding being electromagnetically coupled to the first primary winding, and
wherein the signal output is a second transformer comprising:
a second primary winding having a first end connected to an output of the first amplifier and a second end connected to an output of the second amplifier; and
a second secondary winding having a first end connected to an output end and a second end connected to a ground, the second secondary winding being electromagnetically coupled to the second primary winding.

4. The power amplifier circuit according to claim 3, further comprising:
a first matching circuit that is between the first amplifier and the first filter, and that is configured to supply a second power supply voltage to an input of the first filter; and
a second matching circuit that is between the second amplifier and the second filter, and that is configured to supply the second power supply voltage to an input of the second filter,
wherein the second power supply voltage is supplied to an output of the first filter and an output of the second filter through the second primary winding.

5. The power amplifier circuit according to claim 3, further comprising:
a third matching circuit that is in the first signal path and connects an input of the first filter to the ground in a direct-current manner; and
a fourth matching circuit that is in the second signal path and connects an input of the second filter to the ground in a direct-current manner,
wherein an output of the first filter and an output of the second filter are connected to ground through the second primary winding.

6. The power amplifier circuit according to claim 2, wherein the signal divider is configured to output the fifth signal and the sixth signal such that phases of the fifth signal and the sixth signal are opposite to each other.

7. The power amplifier circuit according to claim 2, wherein the signal divider is configured to output the fifth signal and the sixth signal such that the fifth signal and the sixth signal are in phase with each other.

8. The power amplifier circuit according to claim 7, wherein the signal divider comprises:
a first transmission line in the first signal path; and
a second transmission line in the second signal path.

9. The power amplifier circuit according to claim 1,
wherein the first filter comprises a piezoelectric substrate and a first electrode on the piezoelectric substrate, and
wherein the second filter comprises the piezoelectric substrate and a second electrode on the piezoelectric substrate.

10. A communication device comprising:
a power amplifier circuit comprising:
an amplifier unit that amplifies an input signal and outputs a first signal to a first signal path and a second signal to a second signal path;
a first filter that is provided in the first signal path and outputs a third signal based on the first signal;
a second filter that is provided in the second signal path and outputs a fourth signal based on the second signal; and
a signal output unit that is connected to the first signal path through the first filter and connected to the second signal path through the second filter and outputs an output signal based on the third signal and the fourth signal to a third signal path;
a signal transmission/reception unit that is connected to the signal output unit, outputs the output signal to a transmission/reception terminal of the communication device, and receives a reception signal from the transmission/reception terminal of the communication device; and
a reception signal amplifier that is connected to the signal transmission/reception unit and amplifies the reception signal.

11. The communication device according to claim 10, wherein the signal transceiver comprises:
a first impedance adjustment circuit element between the signal transceiver and the amplifier circuit; and
a second impedance adjustment circuit element between the signal transceiver and the amplifier circuit.

12. A communication device comprising:
an amplifier circuit that is configured to amplify an input signal and to output a first signal to a first signal path and a second signal to a second signal path;
a signal transceiver comprising:
a first duplexer that is in the first signal path and that is configured to output a third signal based on the first signal;
a second duplexer that is in the second signal path and that is configured to output a fourth signal based on the second signal; and
a signal combiner that is connected to the first signal path through the first duplexer and connected to the second signal path through the second duplexer, and that is configured to output an output signal based on the third signal and the fourth signal to a third signal path, to receive a reception signal through the third signal path, and to output a signal based on the reception signal to each of the first duplexer and the second duplexer; and
a reception signal amplifier that is connected to the signal transceiver and that is configured to amplify the reception signal based on the signals from the first duplexer and the second duplexer.

13. The communication device according to claim 12, wherein a frequency of a passband and a frequency of a stopband of the first duplexer are common to a frequency of a passband and a frequency of a stopband of the second duplexer.

14. The communication device according to claim 12,
wherein the signal combiner comprises:
a primary winding having a first end connected to the first duplexer and a second end connected to the second duplexer; and
a secondary winding having a first end connected to the third signal path and a second end connected to ground, and
wherein the primary winding and the secondary winding are electromagnetically coupled to each other.

15. The communication device according to claim 12,
wherein the signal combiner is a first signal combiner,
wherein the signal transceiver further comprises a second signal combiner that is configured to receive the signal from the first duplexer based on the reception signal and the signal from the second duplexer based on the reception signal, and
wherein the reception signal amplifier is configured to amplify a signal output from the second signal combiner.
